(19) United States
(12) Patent Application Publication
(10) Pub. No.: US 2019/0287734 A1
(43) Pub. Date: Sep. 19, 2019

(54) INSTRINSIC STABILITY ENHANCEMENT AND IONIC MIGRATION MITIGATION BY FLUORINATED CATIONS INCORPORATION IN HYBRID LEAD HALIDE PEROVSKITES

(71) Applicant: Qatar Foundation, Doha (QA)

(72) Inventors: Fadwa El-Mellouhi, Doha (QA); Nouar Tabet, Doha (QA); Fahhud Hussain Alharbi, Doha (QA); Abdelhak Belaidi, Doha (QA); Belabbes Merzougui, Doha (QA); Sergey Rashkeev, Doha (QA)

(21) Appl. No.: 16/352,304

(22) Filed: Mar. 13, 2019

Related U.S. Application Data
(60) Provisional application No. 62/642,910, filed on Mar. 14, 2018.

(51) Int. Cl. H01G 9/20; C07F 7/24; H01L 51/00

(52) U.S. Cl. CPC H01G 9/2059; H01L 51/4253; H01L 51/0077; C07F 7/24

(57) ABSTRACT

Disclosed is a method of enhancing thermodynamic stability of a hybrid organic inorganic perovskite through a partial fluorination of CH₃NH³⁺ cation. The method identifies that optimal stability of perovskite material can be reached with low controlled concentration of modified fluorinated cations, which has a tendency to stabilize the material due to the strengthening of some initially weak hydrogen bonds between MA+ cations and surrounding lead-iodide framework. Fluorination also reduces significantly the iodine vacancy mediated diffusion in the perovskite under applied bias voltage.

### CROSS REFERENCE TO RELATED APPLICATIONS

The present application claims priority to U.S. Provisional Patent Application No. 62/642,910, filed on Mar. 14, 2018, the entire content of which is being incorporated herein.

### BACKGROUND

The demand for alternative energy sources has significantly increased recently. This has resulted in the boost of related developments, deployments, and new technologies. The ongoing thrust for hybrid perovskite solar cells (PSC) and materials used therein is in the midst of these developments.

Among perovskite materials, hybrid inorganic-organic methylammonium lead iodide (CH₃NH₃PbI₃) perovskites have drawn attention due to their high photovoltaic (PV) power conversion efficiency (PCE) in conjunction with low-cost chemical process to synthesize the photo absorbing material. Despite the high energy conversion efficiency (ECE) shown by this material in photovoltaic devices, the intrinsic thermodynamic instability of CH₃NH₃PbI₃ is a problem. Instabilities associated with temperature, presence of water and oxygen, ionic mobility, and ultraviolet irradiation hinder the commercial deployment of this family of materials. Enhanced interaction between the dipoles originating from organic molecules in the presence of external electric field was suggested to play an important role in the photoferroic effect in perovskite nanostructured films. Recently, it has been demonstrated that that addition of the 1-methyl-3-(1H,1H,2H,2Hnonafluorohexyl) imidazolium iodide (FIm) dopant salt during the preparation of Cs_{0.05}(MA_{0.15}FA_{0.85})_{0.95}Pb(I_{0.85}Br_{0.15})₃-based perovskites leads to solar cell devices that remain stable for >100 days when stored under atmospheric conditions. However, the additive does not incorporate within the materials, but rather acts as a blocking layer against the interaction with water.

On the other hand, it was suggested that the migration and accumulation of iodide ions under external fields may reduce the open-circuit voltage or the steady-state photocurrent thus affecting the performance of solar cells. Also, it affects non-radiative recombination which causes an appearance of photoluminescence (PL) inactive (or dark) areas on perovskite films.

### SUMMARY

According to one non-limiting aspect of the present disclosure, a method is provided for enhancing stability of lead halide hybrid perovskite. In one embodiment, the method comprises tailoring a chemical environment of methylammonium (MA) cation of the lead halide hybrid perovskite.

According to another non-limiting aspect of the present disclosure, a method comprising changing stability of lead halide hybrid perovskite as a function of fluorination of methylammonium (MA) cation of the lead halide hybrid perovskite is provided.

According to another non-limiting aspect of the present disclosure, a photovoltaic material comprising a partially fluorinated hybrid inorganic-organic perovskite is provided. In one embodiment, the photovoltaic material comprises a material selected from the group consisting of CH₃NH₃PbI₃, CHF₂NH₃PbI₃, CH₂FNH₃PbI₃, and mixtures thereof.

Additional features and advantages are described herein, and will be apparent from the following Detailed Description and the figures.

### BRIEF DESCRIPTION OF THE DRAWING

Features and advantages of the method of enhancing the thermodynamic stability of a hybrid inorganic-organic perovskite, the partially fluorinated hybrid inorganic-organic perovskite and the method of changing stability of a perovskite material described herein may be better understood by reference to the accompanying drawings in which:

FIG. 1 shows bandgap variation as a function of fluorination in CH₃NH₃PbI₃ perovskite.

FIG. 2 shows supercell volume expansion as a function of fluorination in CH₃NH₃PbI₃ perovskite.

FIG. 3 shows stability as a function of fluorination in CH₃NH₃PbI₃ perovskite.

FIG. 4 shows charges at different atomic sites and interatomic distances in fluorinated (CH₂FNH₃)⁺ cation.

FIG. 5 shows fluorinated tetragonal CH₃NH₃PbI₃ perovskite supercell corresponding to 8% fluorine content.

FIG. 6 shows difference of the electrostatic potential for the tetragonal CH₃NH₃PbI₃ perovskite supercell fluorinated by 1 F atom (1F, 4% fluorine content), 2 F atoms (2F, 8% content) and 3 F atoms (3F, 12% content) and the original (no fluorine) CH₃NH₃PbI₃ system as a function of Z-coordinate and averaged over the two other (X- and Y-) coordinates.

FIG. 7 shows difference of the electrostatic potential for the 2×2×2 CH₃NH₃PbI₃ perovskite supercell fluorinated by 1 F atom (1F, 4% fluorine content), 2 F atoms (2F, 8% content) and 3 F atoms (3F, 12% content) and the original (no fluorine) CH₃NH₃PbI₃ system as a function of X-coordinate and averaged over the two other (Z- and Y-) coordinates.

FIG. 8 shows water interaction map of CH₃NH₃PbI₃ perovskite with water before and after fluorination.

FIG. 9 is a cross section side view illustrating an embodiment of a semiconductor device.

The reader will appreciate the foregoing details, as well as others, upon considering the following detailed description of certain non-limiting embodiments of the method of enhancing the thermodynamic stability of a hybrid inorganic-organic perovskite, the partially fluorinated hybrid inorganic-organic perovskite and the method of changing stability of a perovskite material according to the present disclosure. The reader may also comprehend certain of such additional details upon the optoelectronic devices including the partially fluorinated hybrid inorganic-organic perovskite described herein.

### DETAILED DESCRIPTION

The present disclosure provides a method of enhancing thermodynamic stability of a hybrid inorganic-organic perovskite through fluorination of cation CH₃NH₃⁺ which also reduces ionic diffusion, provides a fluorinated hybrid inorganic-organic perovskite with enhanced thermodynamic stability, and also provides a method of changing stability of a perovskite material as a function of fluorination.

In one embodiment, hydrogen in the methylammonium cations CH₃NH₃⁺ of the hybrid inorganic-organic methylammonium lead iodide (CH₃NH₃PbI₃) perovskite material is partially substituted by fluorine. The present inventors conducted a systematic study of the stability of fluorinated perovskite materials with low controlled concentrations of fluorinated methylammonium cations using density functional theory (DFT) for different configurations of cations. The results showed enhanced intrinsic stability of the methylammonium lead iodide perovskite material.

Further, computations focused on successive fluorination of methyl in methylammonium (mono-, bi-, and trifluorination) as a route in enhancing electrostatic interaction of the organic dipoles with the inorganic octahedral framework of P_{b}I₆ besides increasing the dipole strength.

Furthermore, the inventors found that fluorination significantly reduced and possibly mitigated the iodine diffusion in the perovskite under bias because of the resulting geometry related to the electrostatic repulsion between fluorine and iodine negatively charged ions. Iodine diffusion reduction and/or mitigation would enhance the performance of solar cells using this partially fluorinated perovskite.

FIG. 1 shows bandgap variation of the perovskite material as a function of fluorination in CH₃NH₃PbI₃ perovskite. Bandgap standard deviations are obtained corresponding to fluorination contents of 4, 8, and 12% corresponding to the substitution of one, two, and three hydrogen atoms attached to carbon of (CH₃NH₃)⁺ cation by fluorine in 2×2×2 CH₃NH₃PbI₃ perovskite structural supercell. When the fluorination contents are 4, 8, and 12% respectively, the bandgap standard deviations are between −2 and 1. This demonstrates that fluorination has no significant impact on the bandgap. It means that the absorption properties of the CH₃NH₃PbI₃ perovskite materials are conserved.

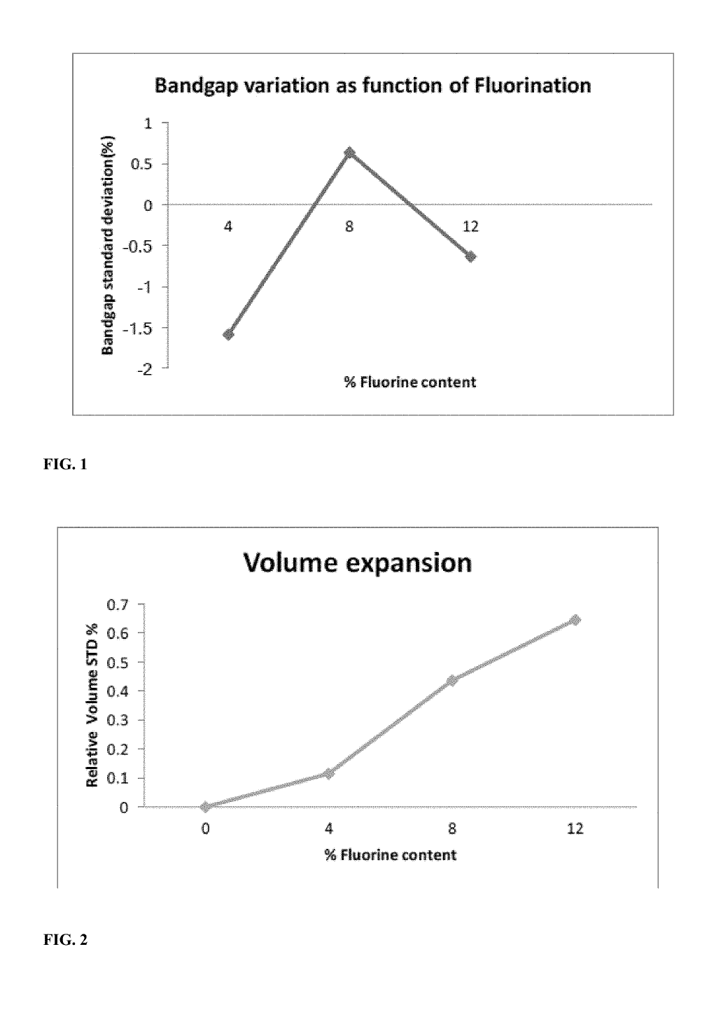

FIG. 2 shows supercell volume expansion of the perovskite material as a function of fluorination in CH₃NH₃PbI₃ perovskite. When the fluorination contents are 4, 8, and 12% respectively in CH₃NH₃PbI₃ perovskite, the relative volume standard deviations are less than 0.7. This demonstrates that fluorination does not cause a significant volume expansion of CH₃NH₃PbI₃ perovskite. The inventors found out that volume expansion does not exceed 1% for up to 12.5% of hydrogen substituted by fluorine in CH₃NH₃PbI₃ perovskite.

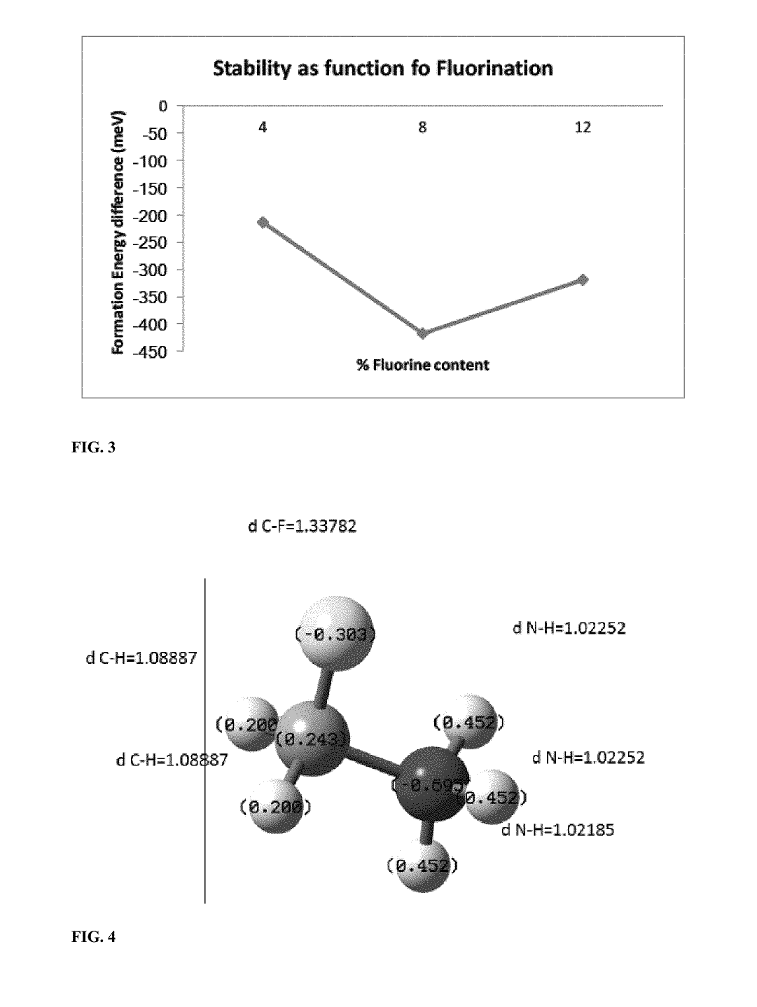

FIG. 3 shows stability of the perovskite material as a function of fluorination in CH₃NH₃PbI₃ perovskite. When the fluorination content in CH₃NH₃PbI₃ perovskite increases from 4% to 8 and 12%, the formation energy difference of the fluorinated material changes from about −200 meV to between −300 and −450 meV. This demonstrates that stability of the perovskite material generally increases with fluorination in CH₃NH₃PbI₃ perovskite.

Without being bound to theory, the inventors believe that this is related to the fact that some initially weak hydrogen bonds between methylammonium and surrounding lead-iodide framework strengthen in the fluorinated material due to internal structural deformations related to the formation of C—F bonds that are longer than C—H bonds, as shown in FIG. 4. FIG. 4 shows charges at different atomic sites and interatomic distances in fluorinated (CH₂FNH₃)⁺ cation.

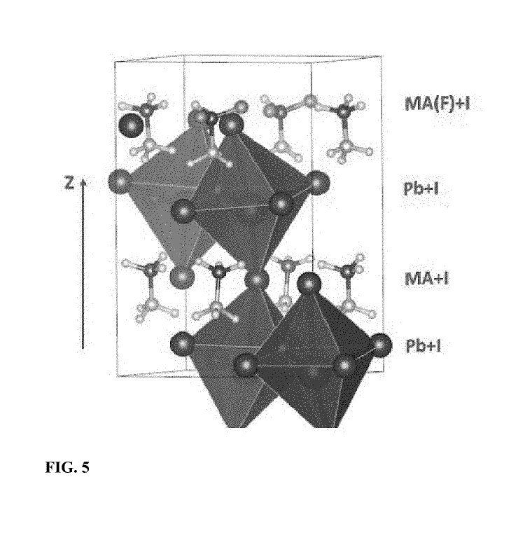

FIG. 5 shows fluorinated tetragonal CH₃NH₃PbI₃ perovskite supercell corresponding to 8% fluorine content. It is energetically favorable to substitute hydrogen in CH₃ group rather that in NH₃ group. Also, fluorinated MA cations (MA(F)) are located in the planes where initially the MA and I species were located (MA-I planes). These planes are perpendicular to the z-axis of the supercell. Therefore, when diffusing in the z-direction, an I-ion should cross the MA(F)-I planes with an excess negative charge. Therefore, the inventors believe that fluorination should significantly reduce and possibly mitigate the iodine diffusion in the perovskite under bias due to the electrostatic repulsion between fluorine and iodine negatively charged ions.

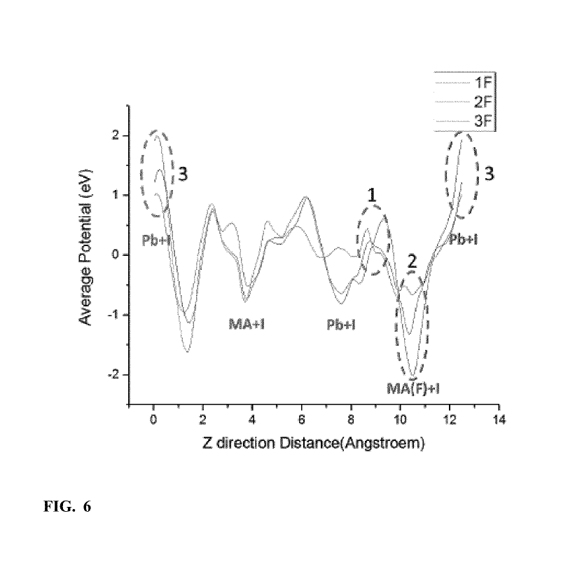

FIG. 6 shows difference of the electrostatic potential for the tetragonal CH₃NH₃PbI₃ perovskite supercell fluorinated by 1 F atom (1F, 4% fluorine content), 2 F atoms (2F, 8% content) and 3 F atoms (3F, 12% content) and the original (no fluorine) CH₃NH₃PbI₃ system as a function of Z-coordinate and averaged over the two other (X- and Y-) coordinates. The ellipses indicate the locations of potential maxima and minima corresponding to energetically favorable locations and energy barriers for negative iodine ions. All fluorine atoms are positioned in one MA(F)-I plane. A “free” iodine ion is negative (with charge (−1)), i.e., potential maxima correspond to most energetically favorable areas for iodine location (points 1 and 3 at the plot) while potential minima—to the energy barrier to come through (point 2). When crossing the MA(F)-I plane, iodine ion should start from the point 1 and go through the barrier at point 2, or start from the point 3 and go through the barrier at point 2.

Table 1 shows energy differences between the positions of local energy minima and energy maxima for fluorinated perovskite with different fluorine contents. Also, it shows how the modification of the cell with fluorine changes the probability of crossing energy barriers by iodine ions (assuming that iodine ions are free species with negative charge (−1)) at room temperature. The crossing probabilities are extremely low, and this indicates that fluorination significantly reduces iodine migration in the Z direction.

TABLE 1
Energy differences between the positions of local energy minima and energy maxima for
fluorinated perovskite with different fluorine contents. The modification of the probability
of crossing energy barriers by iodine ions at room temperature is also shown.

| | Barrier for starting | Probability | Barrier for starting | Probability |
|---|---|---|---|---|
| | from point 3 | of crossing | from point 1 | of crossing |
| Configuration | (E₃₂, eV) | (at 300 K) | (E₁₂, eV) | (at 300 K) |
| 1F (4% F content) | 2.0 | 2.6*10⁻³⁴ | 0.7 | 1.76*10⁻¹² |
| 2F (8% F content) | 2.2 | 1.14*10⁻³⁷ | 1.7 | 2.83*10⁻²⁹ |
| 3F (12% F content) | 3.9 | 3.2*10⁻⁶⁶ | 2.7 | 4.57*10⁻⁴⁶ |

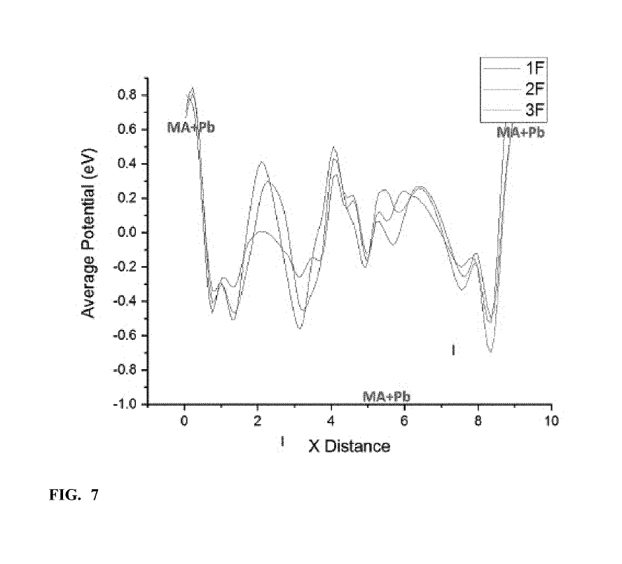

FIG. 7 shows difference of the electrostatic potential for the 2×2×2 CH₃NH₃PbI₃ perovskite supercell fluorinated by 1 F atom (1F, 4% fluorine content), 2 F atoms (2F, 8% content) and 3 F atoms (3F, 12% content) and the original (no fluorine) CH₃NH₃PbI₃ system as a function of X-coordinate and averaged over the two other (Z- and Y-) coordinates. It is clear that modifications of energy barriers for lateral iodine diffusion (parallel to the XY plane) is always much less pronounced than for diffusion in Z-direction, i.e., fluorination makes the iodine diffusion highly anisotropic. The iodine diffusion reduction will result in developing solar cell devices with increased performance reflected in both enhanced device stability and photovoltaic efficiency.

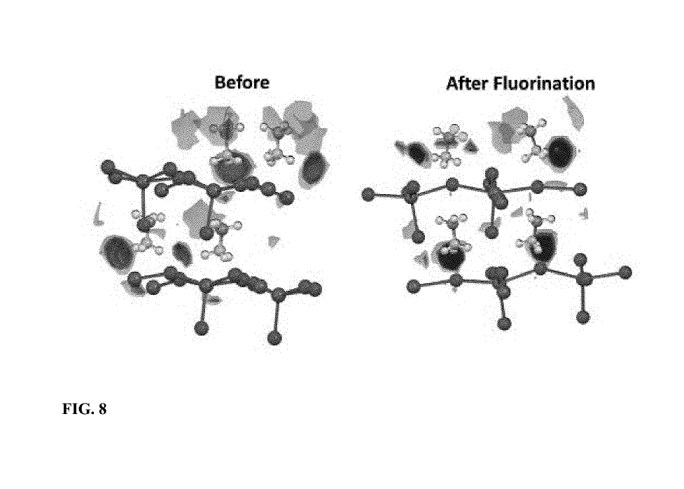

FIG. 8 shows water Interaction map of CH₃NH₃PbI₃ perovskite with water before and after fluorination. It demonstrates a noticeable increase in hydrophobicity. Therefore, fluorination will result in increased hydrophobicity of hybrid inorganic-organic perovskite material CH₃NH₃PbI₃, which may reduce and/or prevent water infiltration to the material.

FIG. 9 illustrates one implementation of the structure and operating principle of a perovskite semiconductor device 100 in which the fluorinated hybrid inorganic-organic perovskite is used. In implementations, a semiconductor device 100 can include, but are not limited to, devices such as photovoltaic devices, light emitting diodes, photodetectors, transistors, radiation sensors, solar cells, memristors, and so forth. As shown in FIG. 9, the semiconductor device 100 may include a cathode layer 101, an anode layer 103, and an active layer 102 disposed between the cathode layer 101 and the anode layer 103. The cathode layer 101 functions as a cathode electrode. The anode layer 103 can include an anode electrode.

In some embodiments, the cathode layer 101 can include an Al layer and/or a Ag layer that functions as a cathode, and the anode layer 103 can include an indium-tin oxide (ITO) layer that functions as an anode. In some other embodiments, the cathode layer 101 can include an indium-tin oxide (ITO) layer that functions as a cathode, and the anode layer 103 can include an aluminum layer that functions as an anode. Other materials may also be used to form the cathode layer 101, such as calcium, magnesium, lithium, sodium, potassium, strontium, cesium, barium, iron, cobalt, nickel, copper, silver, zinc, tin, samarium, ytterbium, chromium, gold, graphene, an alkali metal fluoride, an alkaline-earth metal fluoride, an alkali metal chloride, an alkaline-earth metal chloride, an alkali metal oxide, an alkaline-earth metal oxide, a metal carbonate, a metal acetate, and/or a combination of two or more of the above materials. Further, other materials may be used to form the anode layer 103 (or a transparent electrode), such as fluorine-doped tin oxide (FTO), aluminum-doped zinc oxide (AZO), antimony-tin mixed oxide (ATO), a conductive polymer, a network of metal nanowire, a network of carbon nanowire, nanotube, nanosheet, nanorod, carbon nanotube, silver nanowire, or graphene.

The semiconductor device 100 can include an active layer 102, which can include a photovoltaic perovskite material, which can function as a photovoltaic material. In implementations, the active layer 102 serves to absorb light. In one specific example, an active layer 102 can be configured to absorb light having a wavelength in a first predetermined range, and the anode layer 103 may be transparent to light having a wavelength in a second predetermined range, the second predetermined range overlapping the first predetermined range in a third predetermined range. In this specific example, the semiconductor device 100 may have a high resistivity when not illuminated by any light and may have a low resistivity when illuminated by light having a wavelength in the third predetermined range.

In one embodiment, the active layer 102 can include a fluorinated hybrid inorganic-organic perovskite. In some embodiments, the fluorinated hybrid inorganic-organic perovskite may be a partially fluorinated hybrid inorganic-organic perovskite. In some embodiments, the fluorinated hybrid inorganic-organic perovskite may be a CH₃NH₃PbI₃ perovskite wherein the H in the CH₃NH₃⁺ cation is partially substituted by F.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A method for enhancing stability of lead halide hybrid perovskite, the method comprising tailoring a chemical environment of methylammonium (MA) cation of the lead halide hybrid perovskite.

2. The method of claim 1, comprising partially fluorinating the MA cation.

3. The method of claim 2, wherein two hydrogen (H) atoms of the methyl radical are substituted by two atoms of fluorine (F).

4. The method of claim 2, comprising selectively fluorinating the MA cation.

5. The method of claim 4, wherein the MA cation is partially and selectively fluorinated before or after protonation.

6. The method of claim 1, comprising partially or fully fluorinating the MA cation through a chemical process to form CHₓF_{y}NH₃, wherein x=1, 2, or 3, and y=1, 2, or 3.

7. The method of claim 1, comprising obtaining a fluorinated MA cation represented by formula CHₓF_{y}NH₃, wherein one or both of x=0, 1, or 2 and y=1, 2, or 3.

8. The method of claim 2, wherein the MA cation and the fluorinated MA cation are incorporated with an inorganic matrix of the lead halide hybrid perovskite.

9. The method of claim 8, wherein a dilute concentration of the fluorinated MA cation in the form of CHF₂NH₃ and CH₂FNH₃ leads to enhanced chemical stability without altering main properties of the lead halide hybrid perovskite as a photoabsorber.

10. The method of claim 2, comprising forming a supercell of the lead halide hybrid perovskite comprising a cation selected from the group consisting of CH₃NH₃, CHF₂NH₃, CF₃NH₃, and mixtures thereof.

11. The method of claim 2, wherein the fluorinated MA cations are not additives.

12. A method comprising changing stability of lead halide hybrid perovskite as a function of fluorination of MA cation of the lead halide hybrid perovskite.

13. The method of claim 12, comprising increasing stability of the lead halide hybrid perovskite by increasing the fluorination of the MA cation of the lead halide hybrid perovskite.

14. The method of claim 12, comprising increasing stability of the lead halide hybrid perovskite by including 8% fluorination of the MA cation of the lead halide hybrid perovskite.

15. A photovoltaic material comprising a partially fluorinated hybrid inorganic-organic perovskite.

16. The photovoltaic material of claim 15, wherein the partially fluorinated hybrid inorganic-organic perovskite comprises a fluorinated MA cation represented by formula CHₓF_{y}NH₃, wherein one or both of x=0, 1, or 2 and y=1, 2, or 3.

17. The photovoltaic material of claim 15 comprising a material selected from the group consisting of CH₃NH₃PbI₃, CHF₂NH₃PbI₃, CH₂FNH₃PbI₃, and mixtures thereof.

18. The photovoltaic material of claim 15 comprising CH₃NH₃PbI₃ and at least one of CHF₂NH₃PbI₃ and CH₂FNH₃PbI₃, wherein the at least one of CHF₂NH₃PbI₃ and CH₂FNH₃PbI₃ is incorporated with an inorganic matrix of CH₃NH₃PbI₃.

19. The photovoltaic material of claim 15 having enhanced thermodynamic stability.

20. The photovoltaic material of claim 15 comprising a fully fluorinated MA cation.
